(19) United States
(12) Patent Application Publication
(10) Pub. No.: US 2009/0001995 A1
(43) Pub. Date: Jan. 1, 2009

(54) Circuit for detecting connection failure between printed circuit boards

(75) Inventors: Masaki Satoh, Kawasaki (JP); Toshihiro Ohtani, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/222,310

(22) Filed: Aug. 6, 2008

Related U.S. Application Data
(63) Continuation of application No. PCT/JP2006/302373, filed on Feb. 10, 2006.

(51) Int. Cl. G01R 31/04

(52) U.S. Cl. 324/555

(57) ABSTRACT

A connection failure detection circuit that detects incomplete connection between printed circuit boards. A supervisory signal source is mounted on a first printed circuit board to produce a supervisory signal. A supervisory signal receiver is mounted on the first or second printed circuit board to receive the produced supervisory signal and determine whether the received supervisory signal carries expected logical values. Wiring lines are arranged so as to form a signal path that crosses connectors between the first and second printed circuit boards at at least one point.

This application is a continuing application, filed under 35 U.S.C. §111(a), of International Application PCT/JP2006/302373, filed Feb. 10, 2006.

### BACKGROUND OF THE INVENTION

1. Field of the Invention

The present invention relates to a connection failure detection circuit and, more particularly, to a connection failure detection circuit for detecting connection failure between two printed circuit boards connected via connectors.

2. Description of the Related Art

Electrical connectors are used to interconnect a plurality of printed circuit boards so that electrical signals can propagate between the boards. One conventional method for detecting connection failure between printed circuit boards uses a signal loopback technique. Specifically, a signal with a specific voltage is routed from one printed circuit board to another printed circuit board and then back to the original printed circuit board, where the signal voltage is monitored to detect failure in the connection between the two printed circuit boards.

FIG. 16 is a circuit diagram of the above-described conventional connection failure detection circuit, where the printed circuit boards are not yet connected. One printed circuit board 120 has a DC level detector 121, a connector 122, a resistor R101, and wiring lines 123 and 124. Another printed circuit board 130 has a connector 131 and a wiring line 132.

On the printed circuit board 120, one end of the resistor R101 is connected to a voltage source Vcc, and the other end is connected to a wiring line 123. The wiring line 123 is routed between the connector 122 and the DC level detector 121.

The DC level detector 121 detects a DC voltage on the wiring line 123. More specifically, the DC level detector 121 determines whether the voltage on the wiring line 123 is a ground level voltage or a Vcc level voltage, where the term “Vcc level” refers to a positive voltage of the voltage source Vcc. On the printed circuit board 120, another wiring line 124 connects a terminal of the connector 122 to the ground.

The connector 131 on the opposite printed circuit board 130 mates with the connector 122 of the above-described printed circuit board 120. A wiring line 132 runs between two terminals of this connector 131 so as to short-circuit the wiring lines 123 and 124 on the printed circuit board 120 when the two connectors 122 and 131 are engaged.

FIG. 17 is another circuit diagram of the same conventional connection failure detection circuit. FIG. 17 shows a situation where the two printed circuit boards 120 and 130 are connected together. Since all circuit components shown in FIG. 17 are the same as those described in FIG. 16, the same reference numerals are given to them, and the description will not be repeated here.

As shown in FIG. 17, when the connector 122 is properly coupled to its mating connector 131, the wiring line 123 is connected to the ground through wiring lines 132 and 124. An electric potential difference develops across the resistor R101, while the voltage on the wiring line 123 goes to the ground level.

When the connector 122 is detached from its mating connector 131 as shown in FIG. 16, the voltage on the wiring line 123 goes up to the Vcc level. The DC level detector 121 monitors the voltage level of the wiring line 123, thereby detecting the presence or absence of connection between the connectors 122 and 131.

FIG. 18 shows a change in voltage level of a wiring line. At time point T, when the connector 122 engages with its mating connector 131 shown in FIGS. 16 and 17, the voltage level of the wiring line 123 changes from Vcc level to ground level. As described above, the DC level detector 121 detects the presence or absence of connection between the connectors 122 and 131 by monitoring the voltage level of the wiring line 123.

For efficient transmission of a high-speed signal, all elements along the transmission path, including transmitter circuit, wiring lines on the printed circuit board, connectors, and receiver circuit, have to be equalized in terms of electrical impedance. This is called “impedance matching.” Mismatch in the impedance would distort signal waveforms, thus resulting in a transmission error.

FIG. 19 shows a signal waveform W101 when impedance matching is achieved properly, while FIG. 20 shows a signal waveform W102 in the case where an impedance mismatch is present. Without impedance matching, the transmission signal suffers ringing as shown in the waveform W102 of FIG. 20, whereas almost no ringing is observed in the waveform W101 of FIG. 19 because impedance matching is achieved.

Usually, the impedance of connectors is defined in the state where they are completely engaged with each other. This means that an impedance mismatch could occur when the coupling of connectors is incomplete, as in the case where the connectors are engaged obliquely or coupled loosely in a half-inserted state.

FIG. 21 is a side view of connectors obliquely engaged. Specifically, FIG. 21 shows a printed circuit board 141 and a connector 142 mounted thereon. Also shown are a printed circuit board 143 and a connector 144 mounted thereon.

FIG. 22 is a cross-sectional view of connectors coupled in a half-inserted state. FIG. 22 shows a printed circuit board 151 and connectors 152 and 153 mounted thereon. Also shown are a printed circuit board 154 and connectors 155 and 156 mounted thereon.

When the connectors are obliquely engaged as shown in FIG. 21 or coupled in a half-inserted state as shown in FIG. 22, the contact area of connector terminals is reduced, which results in an impedance mismatch. Further, a space is formed between connector terminals, which could act as a capacitance. This capacitance also leads to an impedance mismatch.

The impedance mismatch produces ringing of the transmitted signal as shown in FIG. 20. Such ringing makes it difficult for the signal to be communicated correctly between the printed circuit boards.

A conventional connection failure detection circuit takes advantage of characteristics of high-frequency signals to detect connection failure within a device, particularly between a circuit board and other components connected to the board (see, for example, Japanese Unexamined Patent Application Publication No. 2005-345209).

However, the above conventional connection failure detection circuit can only determine whether the connectors are completely engaged or completely disengaged, but is unable to detect an incomplete state of connection. That is, the conventional connection failure detection circuit may determine mistakenly that the printed circuit boards are connected properly, despite the fact that the connection is incomplete and an impedance mismatch is present. As a result, the signals could not be properly communicated between the printed circuit boards.

### SUMMARY OF THE INVENTION

In view of the foregoing, it is an object of the present invention to provide a connection failure detection circuit that detects incomplete connection between printed circuit boards.

To accomplish the above-described object, there is provided a connection failure detection circuit for detecting connection failure between first and second printed circuit boards connected via connectors. This connection failure detection circuit comprises: a supervisory signal source mounted on the first printed circuit board to produce a supervisory signal; a supervisory signal receiver mounted on the first or second printed circuit board to receive the supervisory signal produced by the supervisory and determine whether the received supervisory signal carries expected logical values; and wiring lines for delivering the supervisory signal from the supervisory signal source to the supervisory signal receiver, the wiring lines being arranged to form a signal path that crosses the connectors at at least one point.

The above and other objects, features and advantages of the present invention will become apparent from the following description when taken in conjunction with the accompanying drawings which illustrate preferred embodiments of the present invention by way of example.

### BRIEF DESCRIPTION OF THE DRAWINGS

FIG. 1 outlines a connection failure detection circuit according to the present invention;

FIG. 2 is a block diagram of a connection failure detection circuit according to a first embodiment of the invention;

FIG. 3 is a detailed block diagram of a supervisory signal source and a supervisory signal receiver;

FIG. 4 is a detailed block diagram showing another example of the supervisory signal source and supervisory signal receiver;

FIG. 5 illustrates sampling of a supervisory signal by the supervisory signal receiver;

FIG. 6 illustrates impedance of wiring lines running across printed circuit boards;

FIG. 7 illustrates effects of an impedance mismatch in the case where the frequency is low;

FIG. 8 illustrates effects of an impedance mismatch in the case where the frequency is high;

FIG. 9 is a block diagram of a connection failure detection circuit according to a second embodiment of the invention;

FIG. 10 shows a waveform of a supervisory signal in the case where connectors are completely engaged;

FIG. 11 shows a waveform of a supervisory signal in the case where connectors are incompletely engaged;

FIG. 12 is a block diagram of a connection failure detection circuit in the case where LVDS is applied to the supervisory signal;

FIG. 13 is a block diagram of a connection failure detection circuit according to a third embodiment of the invention;

FIG. 14 is a block diagram of a connection failure detection circuit according to a fourth embodiment of the invention;

FIG. 15 is a block diagram of a connection failure detection circuit according to a fifth embodiment of the invention;

FIG. 16 is a circuit diagram of a conventional connection failure detection circuit where printed circuit boards are not yet connected;

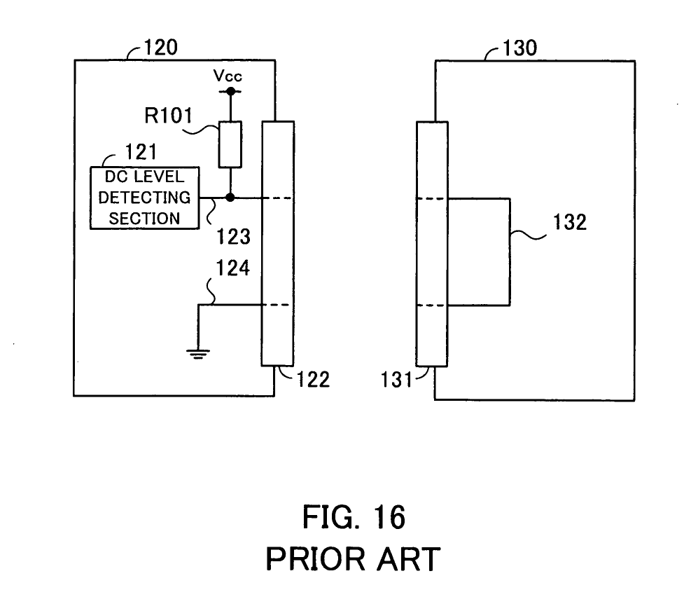

FIG. 17 is another circuit diagram of the conventional connection failure detection circuit where the printed circuit boards are connected;

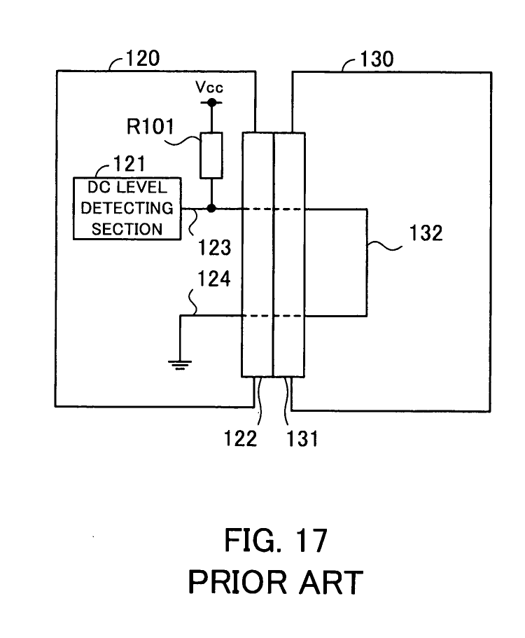

FIG. 18 shows a change in voltage level of a wiring line;

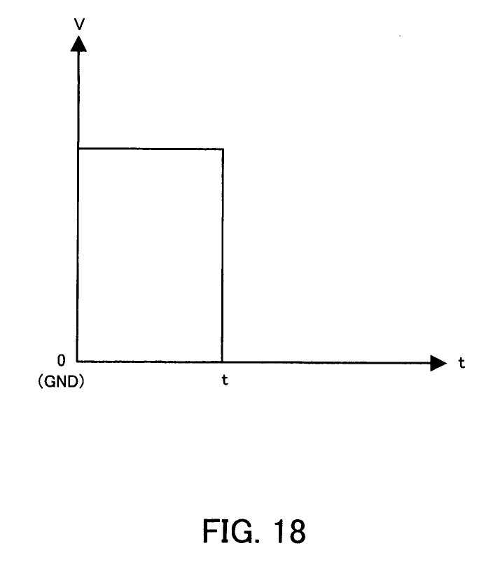

FIG. 19 shows a signal waveform when impedance matching is achieved properly;

FIG. 20 shows a signal waveform in the case where an impedance mismatch is present;

FIG. 21 is a side view of connectors obliquely engaged; and

FIG. 22 is a cross-sectional view of connectors coupled in a half-inserted state.

### DESCRIPTION OF THE PREFERRED EMBODIMENTS

The principle of the present invention will be described in detail below with reference to the accompanying drawings, wherein like reference numerals refer to like elements throughout.

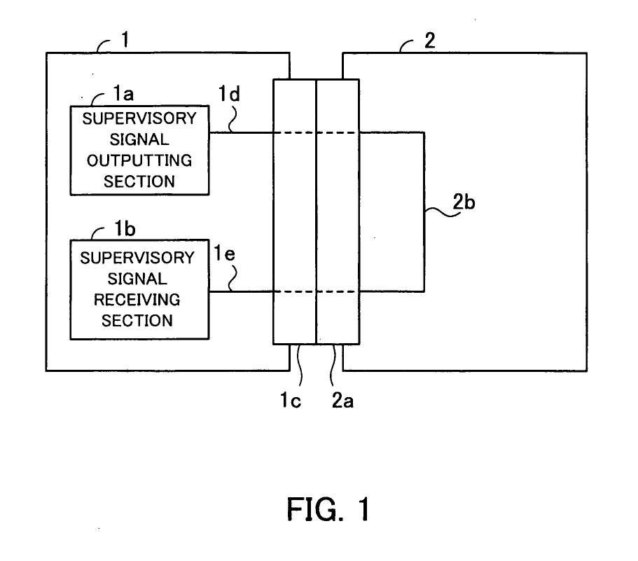

FIG. 1 outlines a connection failure detection circuit according to the present invention. Specifically FIG. 1 shows two printed circuit boards 1 and 2. Connectors 1c and 2a are mounted on those printed circuit boards 1 and 2, respectively. The two printed circuit boards 1 and 2 are electrically connected via the connectors 1c and 2a.

A supervisory signal source 1a is mounted on the printed circuit board 1. This supervisory signal source 1a outputs a supervisory signal. The supervisory signal may be, for example, a clock signal that takes logical values ‘0’ and ‘1’ alternately.

A supervisory signal receiver 1b is mounted on either of the two printed circuit boards 1 and 2. In the example of FIG. 1, the supervisory signal receiver 1b is mounted on the printed circuit board 1. The supervisory signal receiver 1b determines whether the received supervisory signal carries expected logical values. For example, when the above-described clock signal is used as a supervisory signal, the supervisory signal receiver 1b expects to receive a series of alternate logical values ‘0’ and ‘1’ and thus determines whether the supervisory signal is actually received in this way.

Wiring lines 1d, 2b, and 1e bring the output of the supervisory signal source 1a to the input of the supervisory signal receiver 1b when the printed circuit boards 1 and 2 are connected together via the connectors 1c and 2a. As a result, a supervisory signal produced by the supervisory signal source 1a reaches the supervisory signal receiver 1b. The wiring lines 1d, 2b, and 1e are arranged so as to form a signal path that crosses the connectors 1c and 2a at at least one point when the printed circuit boards 1 and 2 are connected. In the example of FIG. 1, the wiring lines 1d, 2b, and 1e provide a signal path that goes from one printed circuit board 1 over to another printed circuit board 2 and then comes back to the original printed circuit board 1, thus crossing the connectors 1c and 2a at two points.

When the connection between the printed circuit boards 1 and 2 is in an incomplete state, or in other words, when the connectors 1c and 2a are not engaged completely, an impedance mismatch occurs between the supervisory signal source 1a and the supervisory signal receiver 1b. The resulting ringing of the supervisory signal from the supervisory signal source 1a hampers the supervisory signal receiver 1b from receiving logical values in the expected way. In the case of the above-described clock signal, the supervisory signal receiver 1b is prevented from receiving a series of alternate logical values ‘0’ and ‘1’ of the clock signal.

As described above, the wiring lines 1d, 2b, and 1e carry the supervisory signal from the supervisory signal source 1a to the supervisory signal receiver 1b, crossing the connectors between the two printed circuit boards 1 and 2 at at least one point. The supervisory signal receiver 1b then determines whether the received supervisory signal carries an expected series of logical values.

Accordingly, when the printed circuit boards 1 and 2 are engaged incompletely, the supervisory signal receiver 1b fails to obtain expected logical values from the received supervisory signal because of impedance mismatching. As a result, the incomplete connection of the printed circuit boards 1 and 2 can be detected.

Next, a first embodiment of the present invention will be described in detail with reference to the accompanying drawings.

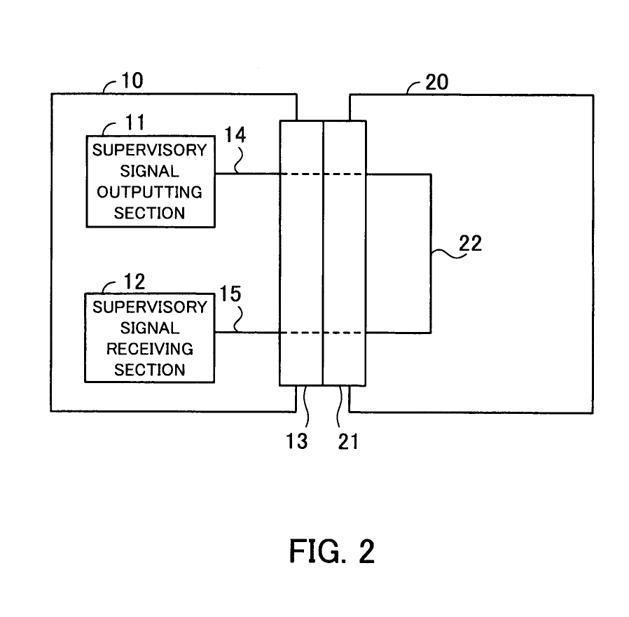

FIG. 2 is a block diagram of a connection failure detection circuit according to a first embodiment of the present invention. FIG. 2 shows two printed circuit boards 10 and 20. One printed circuit board 10 has a supervisory signal source 11, a supervisory signal receiver 12, a connector 13 and wiring lines 14 and 15. The other printed circuit board 20 has a connector 21 and a wiring line 22. Those two printed circuit boards 10 and 20 of FIG. 2 are part of, for example, a data transmission device, one corresponding to its backplane and the other a modular unit connected to that backplane. Alternatively, the printed circuit boards 10 and 20 may be modular units connected to each other.

The supervisory signal source 11 on the printed circuit board 10 outputs a supervisory signal for detecting the state of connection between the connectors 13 and 21 (or connection between the printed circuit boards 10 and 20). The supervisory signal may be, for example, a square-wave signal that takes logical values of ‘0’ and ‘1’.

The supervisory signal receiver 12 receives the supervisory signal produced by the supervisory signal source 11. The supervisory signal receiver 12 determines whether the received supervisory signal carries expected logical values ‘0’ and ‘1’. The result of this determination indicates the connection state of the printed circuit boards 10 and 20.

A connector 13 is mounted on the printed circuit board 10, and a wiring line 14 runs from a terminal of this connector 13 to the output of the supervisory signal source 11. Another wiring line 15 interconnects the input of the supervisory signal receiver 12 and another terminal of the connector 13.

A connector 21 is mounted on the printed circuit board 20. This connector 21 is adapted to fit into the connector 13 on the printed circuit board 10. A wiring line 22 is routed between two terminals of the connector 21 so as to short-circuit the wiring lines 14 and 15 on the printed circuit board 10 when the connectors 13 and 21 are engaged. The wiring lines 14, 15, and 22 are arranged so as to form a signal path that crosses the connectors 13 and 21 at at least one point when the printed circuit boards 10 and 20 are connected.

When the connectors 13 and 21 are engaged, the output of the supervisory signal source 11 is connected to the input of the supervisory signal receiver 12 via the path that goes through the wiring line 14, connectors 13 and 21, and wiring line 22, then back through the connectors 21 and 13 and wiring line 15. In other words, when the connectors 13 and 21 are engaged, the supervisory signal from the supervisory signal source 11 reaches the supervisory signal receiver 12. The supervisory signal receiver 12 detects logical values ‘0’ and ‘1’ of the received supervisory signal, thereby identifying the connection state between the printed circuit boards 10 and 20.

Next, the supervisory signal source 11 and supervisory signal receiver 12 of FIG. 2 will be described in detail.

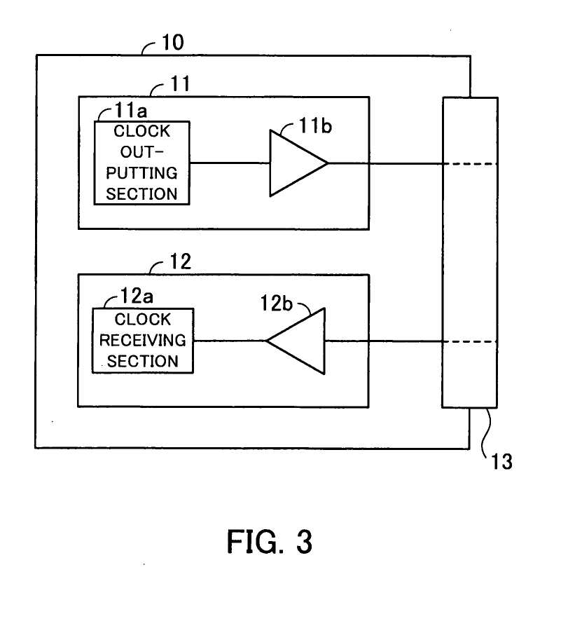

FIG. 3 is a detailed block diagram of the supervisory signal source 11 and the supervisory signal receiver 12. As shown in FIG. 3, the supervisory signal source 11 has a clock signal source 11a and a driver 11b. The supervisory signal receiver 12 has a clock signal receiver 12a and a driver 12b. Also shown in FIG. 3 are a printed circuit board 10 and a connector 13 mounted thereon, which are the same as those shown in FIG. 2.

The clock signal source 11a of the supervisory signal source 11 generates a clock signal that takes logical values ‘0’ and ‘1’ alternately. The driver 11b amplifies the clock signal generated by the clock signal source 11a and outputs the amplified signal.

The driver 12b of the supervisory signal receiver 12 receives the clock signal generated by the clock signal source 11a when the connectors 13 and 21 are engaged. The driver 12b amplifies the incoming clock signal and supplies the amplified signal to the clock signal receiver 12a. The clock signal receiver 12a detects the clock signal and determines whether it carries a series of alternate logical values ‘0’ and ‘1’.

In operation, the clock signal source 11a outputs a clock signal that takes logical values ‘0’ and ‘1’ alternately. When the connectors 13 and 21 are completely engaged, the clock signal receiver 12a detects a series of alternate logical values ‘0’ and ‘1’. If the coupling of the connectors 13 and 21 was incomplete, the resulting ringing of the clock signal would prevent the clock signal receiver 12a from alternately detecting logical values ‘0’ and ‘1’. This enables detection of the connection state of the printed circuit boards 10 and 20.

Next, another example of the supervisory signal source 11 and supervisory signal receiver 12 of FIG. 2 will be described in detail.

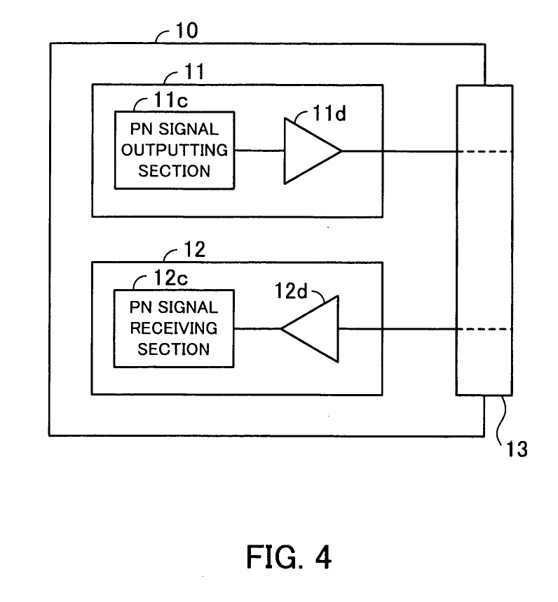

FIG. 4 is a detailed block diagram showing another example of the supervisory signal source 11 and supervisory signal receiver 12. As shown in FIG. 4, the supervisory signal source 11 has a PN (Pseudo-random Noise) signal source 11c and a driver 11d. The supervisory signal receiver 12 has a PN signal receiver 12c and a driver 12d. Also shown in FIG. 4 are a printed circuit board 10 and a connector 13 mounted thereon, which are the same as those shown in FIG. 2.

The PN signal source 11c of the supervisory signal source 11 generates a clock signal with a PN pattern. The number of stages and the frequency of this PN clock signal are previously determined at the time of design. The driver 11d amplifies the PN clock signal generated by the PN signal source 11c and outputs the amplified signal.

The driver 12d of the supervisory signal receiver 12 receives the PN clock signal generated by the PN signal source 11c when the connectors 13 and 21 are engaged. The driver 12d amplifies the incoming PN clock signal and supplies the amplified signal to the PN signal receiver 12c. The PN signal receiver 12c is supposed to reproduce a clock signal with a PN pattern having the same predetermined stage number and the same predetermined frequency as those of the original PN clock signal produced by the PN signal source 11c. The PN signal receiver 12c compares the PN pattern of the PN clock signal supplied from the driver 12d with that of the original PN clock signal, thereby determining whether the PN patterns match with each other.

In operation, the PN signal source 11c generates a clock signal with a specific PN pattern, and the PN signal receiver 12c reproduces the same PN pattern from a received PN clock signal. The PN signal receiver 12c compares the reproduced PN pattern with the original one, which are supposed to match with each other when the connectors 13 and 21 are completely engaged. If the coupling of the connectors 13 and 21 was incomplete, the resulting ringing of the received PN clock signal would cause a mismatch in the PN patterns. This enables detection of the connection state of the printed circuit boards 10 and 20.

Next, sampling of a supervisory signal by the supervisory signal receiver 12 of FIG. 2 will be described.

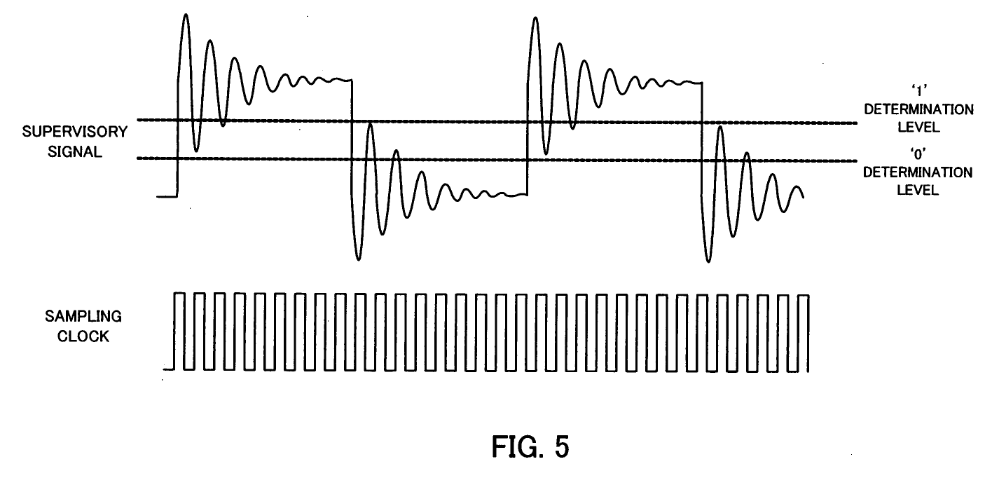

FIG. 5 illustrates how the supervisory signal receiver 12 samples a supervisory signal. Specifically, FIG. 5 shows a supervisory signal received by the supervisory signal receiver 12 and a sampling clock indicating the timing for determining the signal's instantaneous logical value ‘0’ or ‘1’. The supervisory signal receiver 12 makes this determination at each rising edge of the sampling clock, for example.

By selecting a sampling clock frequency higher than the supervisory signal frequency as shown in FIG. 5, the supervisory signal receiver 12 performs the sampling multiple times in each bit interval of the supervisory signal. The use of a higher sampling frequency enables more sensitive detection of waveform distortion (e.g., ringing) of the supervisory signal, which may be caused by incomplete connection between the connectors 13 and 21.

While the above description assumes sampling operations performed by the supervisory signal receiver 12 of FIG. 2, the same concept can also be applied to the clock signal receiver 12a shown in FIG. 3 and the PN signal receiver 12c shown in FIG. 4.

Next, characteristic impedance of the printed circuit boards 10 and 20 of FIG. 2 will be described.

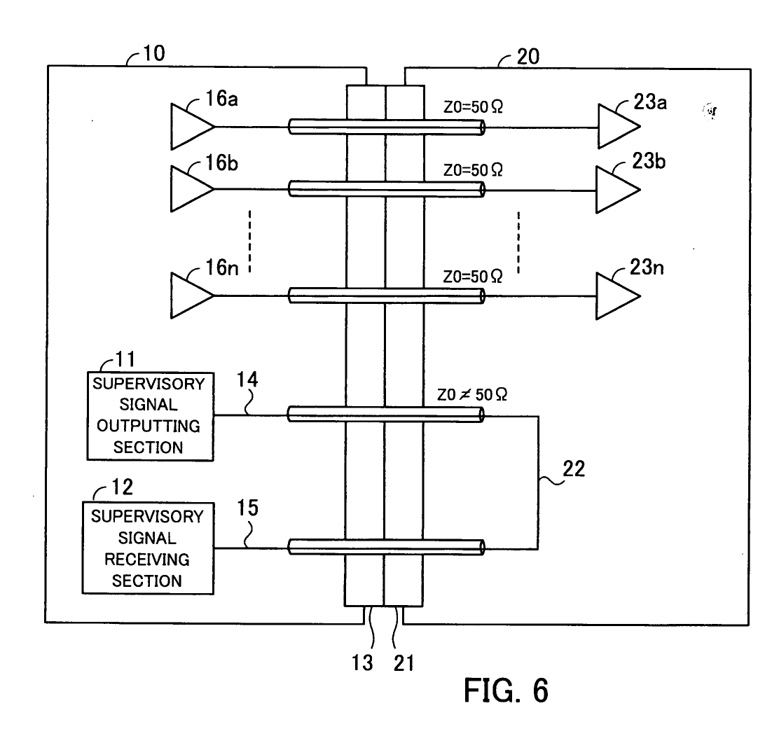

FIG. 6 illustrates circuits on the printed circuit boards 10 and 20 and their characteristic impedance. Since all circuit components shown in FIG. 6 are the same as those described in FIG. 2, the same reference numerals are given to them, and the description will not be repeated here.

The illustrated printed circuit board 10 exchanges signals with another printed circuit board 20. Specifically, transmitting elements 16a, 16b, . . . , 16n on the printed circuit board 10 transmit signals to receiving elements 23a, 23b, . . . , 23n on the printed circuit board 20. The signals produced by the transmitting elements 16a, 16b, . . . , 16n have a frequency of, for example, 100 MHz, which is high enough to require impedance matching. The supervisory signal produced by the supervisory signal source 11 also has a frequency that is high enough to require impedance matching. Specifically, the supervisory signal has the same frequency as those of the signals from the transmitting elements 16a, 16b, . . . , 16n.

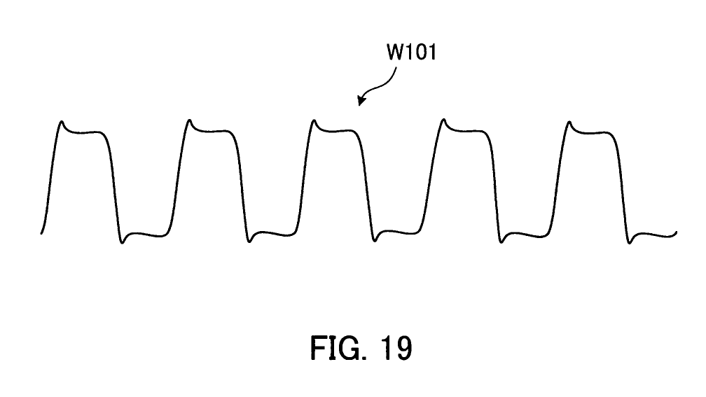

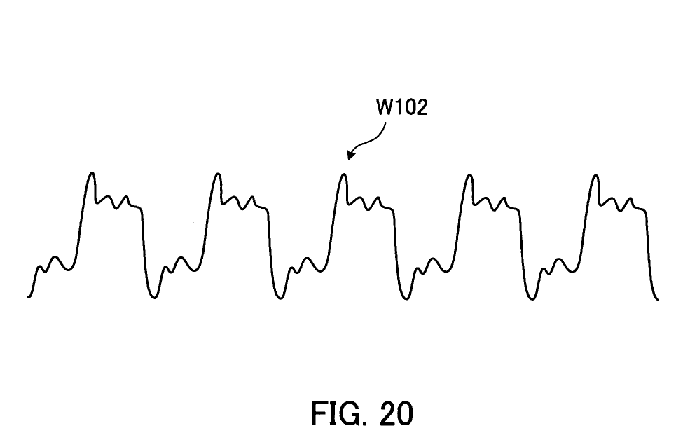

The circuit designer considers matching of the output impedance of transmitting elements 16a, 16b, . . . , 16n, input impedance of receiving elements 23a, 23b, . . . , 23n, and characteristic impedance of transmission lines (wiring lines) connecting those transmitting elements 16a, 16b, . . . , 16n with the corresponding receiving elements 23a, 23b, . . . , 23n. Impedance matching is required because an impedance mismatch will cause ringing distortion on transmitted signals, as discussed in FIGS. 19 and 20, thus preventing the signals from being correctly received.

The present embodiment, on the other hand, deliberately introduces an impedance mismatch in the circuit formed from the supervisory signal source 11 and supervisory signal receiver 12 and a transmission line interconnecting them. Note, however, that the degree of impedance mismatching is selected within a range where the supervisory signal receiver 12 can correctly distinguish the logical values ‘0’ and ‘0’ of the supervisory signal when the connectors 13 and 21 are completely engaged.

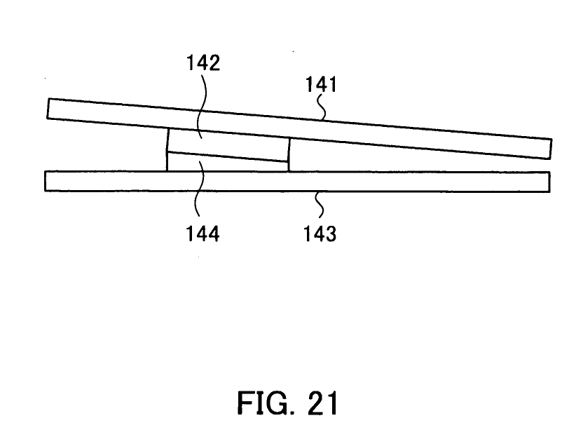

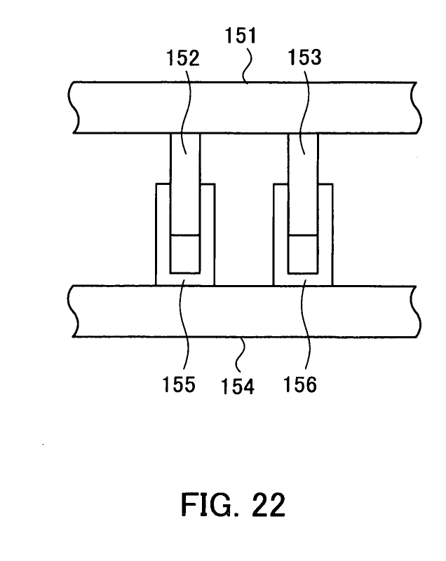

The above circuit design makes the supervisory signal more vulnerable to impedance mismatching caused by an incomplete coupling of the connectors 13 and 21, as in the case shown in FIGS. 21 and 22. In other words, the proposed connection failure detection circuit can detect incomplete connection of the connectors 13 and 21 more sensitively.

Suppose, for example, that all the transmitting elements 16a, 16b, . . . , 16n, receiving elements 23a, 23b, . . . , 23n, supervisory signal source 11, and supervisory signal receiver 12 have an impedance of 50Ω. In this case, the transmission lines interconnecting the transmitting elements 16a, 16b, . . . , 16n and receiving elements 23a, 23b, . . . , 23n are designed to have a characteristic impedance of 50Ω. On the other hand, the transmission line running between the supervisory signal source 11 and the supervisory signal receiver 12 is designed to have a characteristic impedance of 40Ω or 60Ω, for example.

Alternatively, the circuit designer may design the circuit so as to achieve impedance matching throughout the supervisory signal source 11, the supervisory signal receiver 12, and the transmission line therebetween. Even in this case, the matching impedance would be spoiled by incomplete coupling of the connectors 13 and 21. With the resulting ringing of the supervisory signal, the connection failure detection circuit can detect the incomplete connection between the connectors 13 and 21.

The above example assumes that the supervisory signal has the same frequency as other signals. Alternatively, the frequency of the supervisory signal may be higher than that of other signals. This design makes the supervisory signal more vulnerable to an impedance mismatch at incompletely coupled connectors 13 and 21. Accordingly, the incomplete connection between the connectors 13 and 21 can be detected more sensitively.

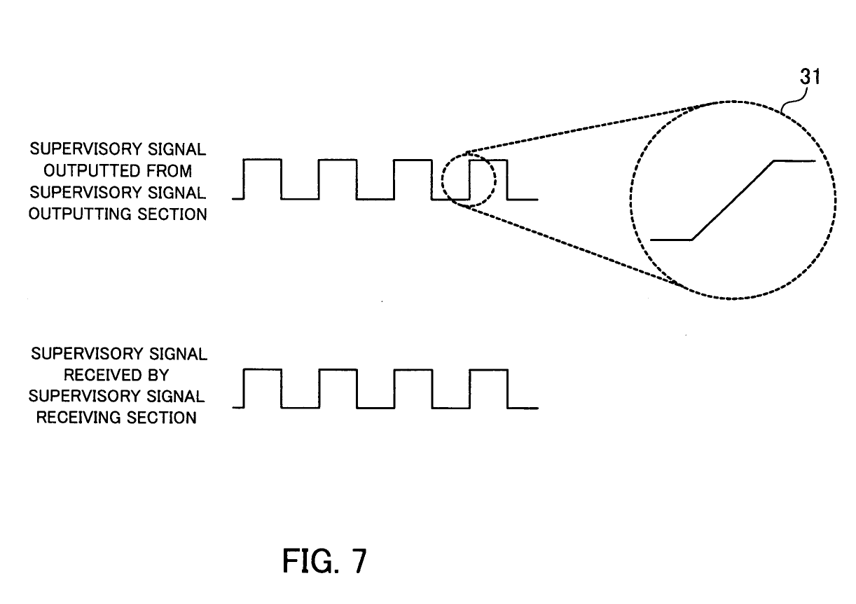

FIG. 7 illustrates effects of an impedance mismatch when the frequency is low. Specifically, FIG. 7 shows a supervisory signal received by the supervisory signal receiver 12 in comparison with its original signal produced by the supervisory signal source 11.

When the frequency of the supervisory signal is low, the slopes of rising and falling edges of the supervisory signal are relatively gentle as shown in the enlarged view 31 of FIG. 7. Accordingly, even when an impedance mismatch is present at incompletely coupled connectors 13 and 21, the supervisory signal receiver 12 would observe little ringing on the received supervisory signal.

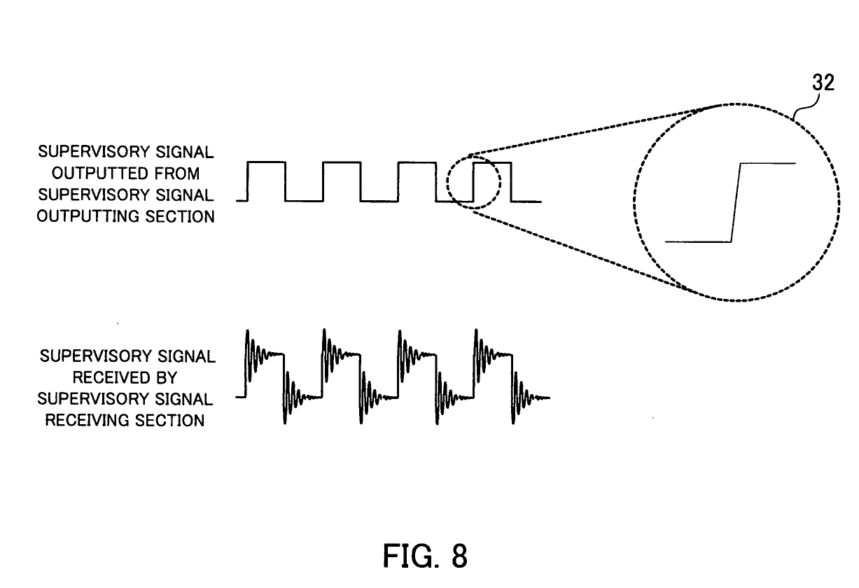

FIG. 8 illustrates effects of an impedance mismatch when the frequency is high. Specifically, FIG. 8 shows a supervisory signal received by the supervisory signal receiver 12 in comparison with its original signal produced by the supervisory signal source 11.

When the frequency of the supervisory signal is high, the slopes of rising and falling edges of the supervisory signal are steep as shown in the enlarged view 32 of FIG. 8. Accordingly, with an impedance mismatch at the incompletely coupled connectors 13 and 21, the supervisory signal will have a large ringing when it arrives at the supervisory signal receiver 12.

Thus, the supervisory signal becomes more vulnerable to impedance mismatching by giving it a higher frequency than other signals. With this setup, the connection failure detection circuit can detect incomplete connection of connectors 13 and 21 more sensitively.

As described above, the supervisory signal produced by the supervisory signal source 11 is transmitted to the supervisory signal receiver 12 over the wiring lines 14, 22 and 15, which cross the connectors between the two printed circuit boards 10 and 20 at at least one point. The supervisory signal receiver 12 then determines whether the received supervisory signal carries an expected series of logical values.

Accordingly, when the printed circuit boards 10 and 20 are engaged incompletely, the supervisory signal receiver 12 fails to obtain expected logical values from the received supervisory signal because of impedance mismatching. As a result, the incomplete connection of the printed circuit boards 10 and 20 can be detected.

The proposed technique detects incomplete connection of connectors 13 and 21 without quantitatively measuring the impedance, thus eliminating the need for additional circuits or devices for such measurement.

Referring back to FIG. 2, both the supervisory signal source 11 and supervisory signal receiver 12 are mounted on the same printed circuit board 10. The present invention, however, should not be limited to this specific configuration, but the supervisory signal source 11 and supervisory signal receiver 12 may be mounted on separate printed circuit boards. For example, the supervisory signal receiver 12 may be mounted on the opposite printed circuit board 20.

The present invention may also be applied to the case where a cable is interposed between the two connectors 13 and 21. The supervisory signal receiver 12 can successfully detect incomplete connection between the printed circuit boards 10 and 20 also in this case since an impedance mismatch at either end of the cable connection would hamper the supervisory signal from delivering expected logical values.

Next, a second embodiment of the present invention will be described in detail with reference to the accompanying drawings. In the second embodiment, differential signaling is used to send a supervisory signal.

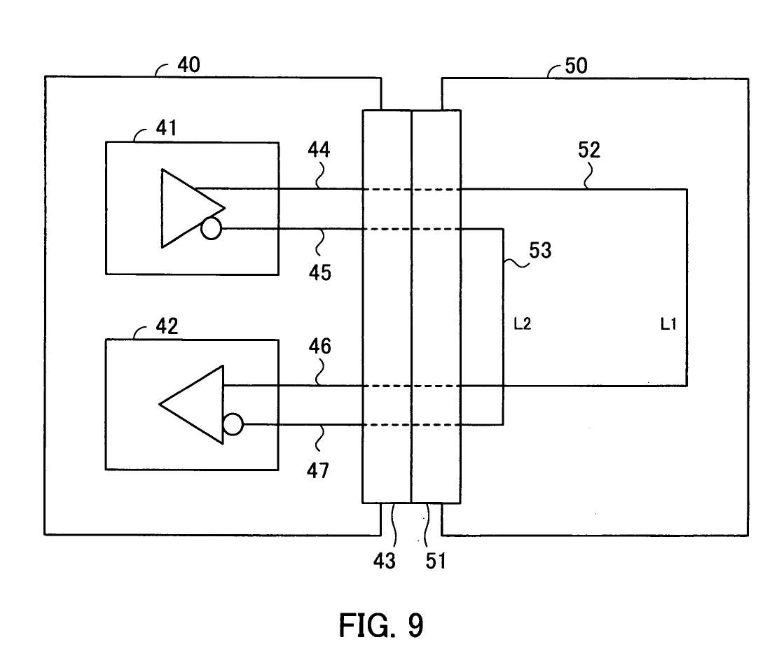

FIG. 9 is a block diagram of a connection failure detection circuit according to the second embodiment. Specifically, FIG. 9 shows two printed circuit boards 40 and 50. One printed circuit board 40 has a supervisory signal source 41, a supervisory signal receiver 42, a connector 43, and wiring lines 44 to 47. The other printed circuit board 50 has a connector 51, and wiring lines 52 and 53. Those two printed circuit boards 40 and 50 of FIG. 9 are part of, for example, a data transmission device, one corresponding to its backplane and the other a modular unit connected to that backplane. Alternatively, the printed circuit boards 40 and 50 may correspond to modular units connected to each other.

The supervisory signal source 41 on the printed circuit board 40 has the same function as that of the supervisory signal source 11 illustrated in FIG. 2. However, the second embodiment differs from the first embodiment in that the supervisory signal source 41 produces a differential signal as a supervisory signal.

The supervisory signal receiver 42 has the same function as that of the supervisory signal receiver 12 illustrated in FIG. 2. However, the second embodiment differs from the first embodiment in that the supervisory signal receiver 42 is designed to receive a differential supervisory signal.

A connector 43 is mounted on the printed circuit board 40, and wiring lines 44 and 45 are routed between terminals of this connector 43 and the differential outputs of the supervisory signal source 41. Wiring lines 46 and 47 are routed between the differential inputs of the supervisory signal receiver 42 and another two terminals of the connector 43. Those wiring lines 44, 45, 46, and 47 are designed to carry a differential supervisory signal.

A connector 51 is mounted on the printed circuit board 50. This connector 51 is adapted to fit into its mating connector 43 on the printed circuit board 40. Wiring lines 52 and 53 are routed between two pairs of terminals of the connector 51 so as to short-circuit the wiring lines 44 and 45 and the wiring lines 46 and 47, respectively, when the connectors 43 and 51 are engaged. The wiring lines 44 to 47, 52, and 53 are arranged so as to form a path that crosses the connectors 43 and 51 at at least one point when the printed circuit boards 40 and 50 are connected.

When the connectors 43 and 51 are engaged, the output of the supervisory signal source 41 is connected to the input of the supervisory signal receiver 42 through the wiring lines 44 and 45, the connectors 43 and 51, the wiring lines 52 and 53, the connectors 51 and 43, and the wiring lines 46 and 47. In other words, when the connectors 43 and 51 are engaged, the differential supervisory signal reaches the supervisory signal receiver 42. The supervisory signal receiver 42 detects logical values of the received supervisory signal, thereby identifying the connection state between the printed circuit boards 40 and 50.

The transmission lines carrying two complementary supervisory signals have different lengths. For example, the transmission line formed from wiring lines 44, 52, and 46 has a length of L1, while that formed from wiring lines 45, 53, and 47 has a length of L2. A difference in length of those differential transmission lines makes the supervisory signal more sensitive to impedance mismatching (i.e., its waveform will be distorted easily). It is therefore possible to detect incomplete connection between the printed circuit boards 40 and 50 more easily by taking advantage of the above nature of differential signaling.

The following will describe how the waveform of a differential supervisory signal is affected by a difference in propagation delay.

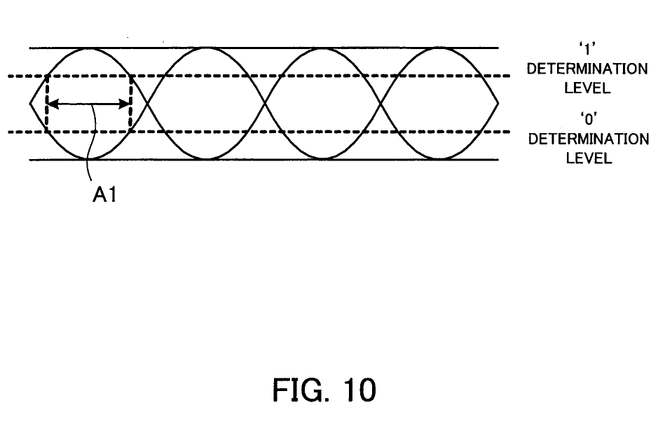

FIG. 10 shows a waveform of a supervisory signal in the case where connectors are completely engaged. Since impedance matching is achieved when the connectors 43 and 51 are completely engaged, the supervisory signal appears as shown in FIG. 10. The supervisory signal receiver 42 can discriminate logical values ‘0’ and ‘0’ of this supervisory signal with its wide eye width as indicated by the bidirectional arrow A1 in FIG. 10.

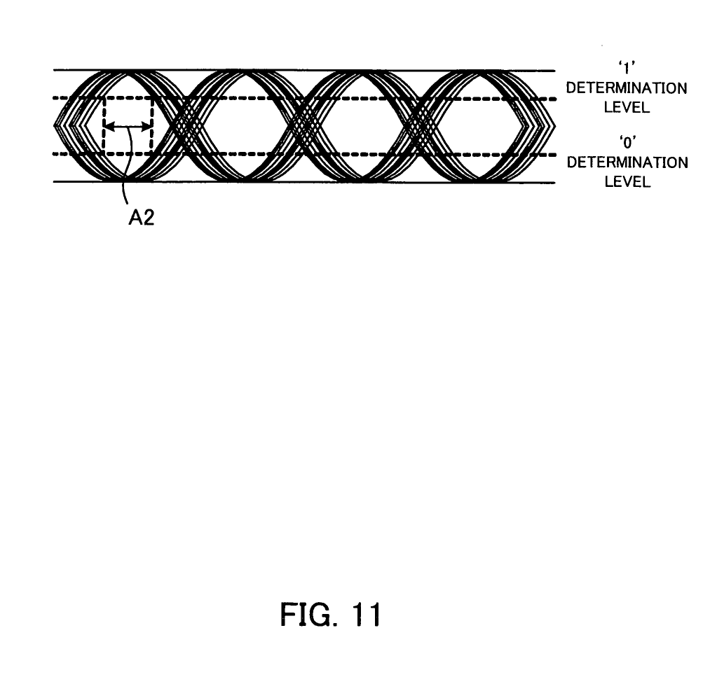

FIG. 11 shows a waveform of a supervisory signal in the case where connectors are incompletely engaged. Since an impedance mismatch occurs when the connectors 43 and 51 are incompletely engaged, the complementary signals of the supervisory signal experience jitters as shown in FIG. 11.

This is because of a difference in length between two parallel transmission lines, which leads to a difference in propagation times of the two complementary signals. Therefore, the opening of their eye pattern, which indicates how distinctively logical values ‘0’ and ‘0’ can be recognized, becomes narrower as indicated by the bidirectional arrow A2 in FIG. 11.

Thus, by giving different lengths to the two parallel transmission lines carrying a supervisory signal, incomplete connection between the printed circuit boards 40 and 50 can be detected more sensitively.

Even in the case of equal transmission line lengths, incomplete connection between the connectors 43 and 51 can be detected.

LVDS (Low Voltage Differential Signaling) techniques may be used with the present embodiment. With LVDS, the characteristic impedance of differential transmission lines is set to 50Ω and a terminating resistor of 100Ω is inserted between the lines at the receiving end in order to achieve impedance matching. When LVDS is used to deliver the supervisory signal, selecting a terminating resistor value other than 100Ω would produce an impedance mismatch as in the case illustrated in FIG. 6.

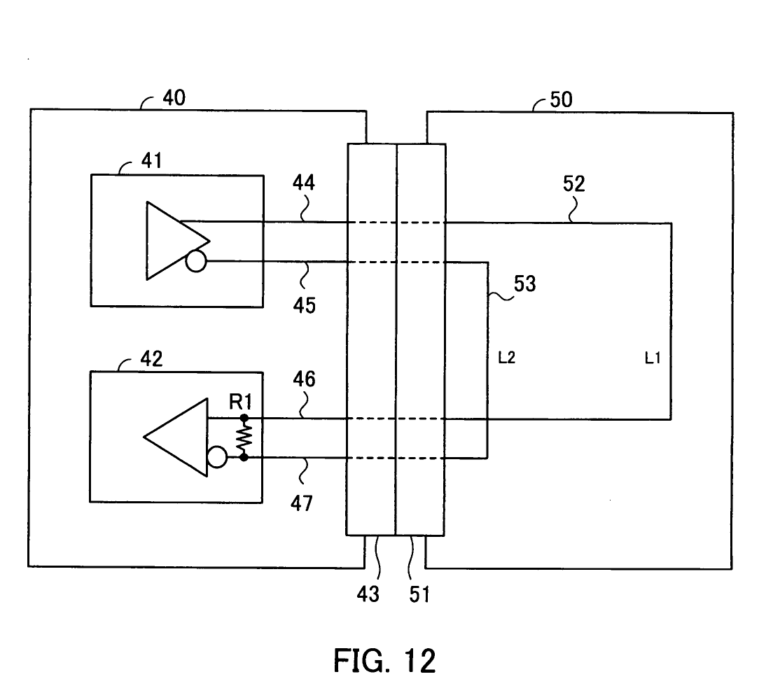

FIG. 12 is a block diagram of a connection failure detection circuit in the case where LVDS is applied to the supervisory signal. Since all circuit components shown in FIG. 12 are the same as those described in FIG. 9, the same reference numerals are given to them, and the description will not be repeated here.

In the LVDS-based connection failure detection circuit of FIG. 12, a terminating resistor R1 is placed at the input of the supervisory signal receiver 42 to terminate the incoming supervisory signal.

Basically the LVDS requires this terminating resistor R1 to be set to 100Ω. According to the present embodiment, however, a different resistance is chosen for the terminating resistor R1, rather than setting it to 100Ω. Note, however, that the resistance value of the terminating resistor R1 should be within a range that permits the supervisory signal receiver 42 to correctly determine the logical values ‘0’ and ‘0’ of an incoming supervisory signal when the connectors 43 and 51 are completely engaged.

Thus, by selecting a resistance value other than 100Ω for the terminating resistor R1, the supervisory signal becomes more vulnerable to impedance mismatching. For this reason, the proposed connection failure detection circuit can detect incomplete connection between the printed circuit boards 40 and 50 more sensitively.

As can be seen from the above description, the present embodiment detects incomplete connection between the printed circuit boards 40 and 50, not only in the case of single-ended supervisory signals, but also in the case where a differential signaling technique is used to deliver supervisory signals.

In FIGS. 9 and 12, both the supervisory signal source 41 and supervisory signal receiver 42 are mounted on the same printed circuit board 40. The present invention is not limited to this specific configuration, but the supervisory signal source 41 and supervisory signal receiver 42 may be mounted on separate printed circuit boards. For example, the supervisory signal receiver 42 may be mounted on the opposite printed circuit board 50.

Also in the second embodiment, the supervisory signal may be a clock signal that takes logical values ‘0’ and ‘0’ alternately. Or, alternatively, the supervisory signal may be a PN pattern signal, which works in the same manner as in the first embodiment. Further, the frequency of sampling supervisory signals in the supervisory signal receiver 42 may be higher than that of the supervisory signal itself. In addition, the supervisory signal may have a higher frequency than other signals as discussed in the first embodiment.

Next, a third embodiment according to the present invention will be described in detail with reference to the accompanying drawings. Unlike the foregoing first embodiment in which one supervisory signal source and one supervisory signal receiver are provided, the third embodiment uses a plurality of supervisory signal sources and a plurality of supervisory signal receivers.

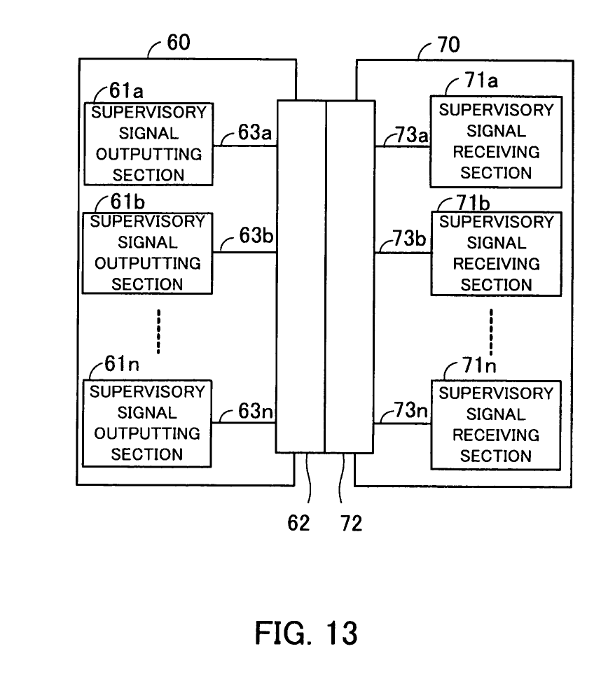

FIG. 13 is a block diagram of a connection failure detection circuit according to the third embodiment. Specifically, FIG. 13 shows two printed circuit boards 60 and 70. One printed circuit board 60 has supervisory signal sources 61a, 61b, . . . , 61n, a connector 62, and wiring lines 63a, 63b, . . . , 63n. Another printed circuit board 70 has supervisory signal receivers 71a, 71b, . . . , 71n, a connector 72, and wiring lines 73a, 73b, . . . , 73n. Those two printed circuit boards 60 and 70 of FIG. 13 are part of, for example, a data transmission device, one corresponding to its backplane and the other corresponding to a modular unit connected to the backplane. Alternatively, the printed circuit boards 60 and 70 may be modular units connected to each other.

Each supervisory signal source 61a, 61b, . . . , 61n on the printed circuit board 60 has the same function as that of the supervisory signal source 11 illustrated in FIG. 2 and therefore, its description will not be repeated here. Further, each supervisory signal receiver 71a, 71b, . . . , 71n of the printed circuit board 70 has the same function as that of the supervisory signal receiver 12 illustrated in FIG. 2 and therefore, its description will not be repeated here.

On the printed circuit board 60, a wiring line 63a is routed between the output of the supervisory signal source 61a and a terminal of the connector 62. Similarly, wiring lines 63b, . . . , 63n are routed between the outputs of the other supervisory signal sources 61b, . . . , 61n and their corresponding terminals of the connector 62.

On the printed circuit board 70, a wiring line 73a is routed between the input of the supervisory signal receiver 71a and a terminal of the connector 72. Similarly, wiring lines 73b, . . . , 73n are routed between the inputs of the supervisory signal receivers 71b, . . . , 71n and their corresponding terminals of the connector 72.

The connector 62 and its mating connector 72 are adapted to fit into each other. When those connectors 62 and 72 are completely engaged, two wiring lines 63a and 73a are connected together. Likewise, the other pairs of wiring lines (i.e., wiring lines 63b and 73b, . . . , and wiring lines 63n and 73n) are connected together. This means that the supervisory signal source 61a and its corresponding supervisory signal receiver 71a can communicate a signal, as can the other source-receiver pairs (i.e., supervisory signal source 61b and supervisory signal receiver 71b, . . . , and supervisory signal source 61n and supervisory signal receiver 71n). Each pair of wiring lines is arranged so as to form a signal path that crosses the connectors 62 and 72 at at least one point when the printed circuit boards 60 and 70 are connected.

That is, when the connectors 62 and 72 are engaged, a supervisory signal produced by the supervisory signal source 61a propagates to the supervisory signal receiver 71a. Likewise, a supervisory signal produced by the supervisory signal source 61b propagates to the supervisory signal receiver 71b. In the same manner, a supervisory signal produced by the supervisory signal source 61n propagates to the supervisory signal receiver 71n. The supervisory signal receivers 71a, 71b, . . . , 71n detect those supervisory signals received from the supervisory signal sources 61a, 61b, . . . , 61n, thereby identifying connection state between the printed circuit boards 60 and 70.

With multiple supervisory signal sources 61a, 61b, . . . , 61n and multiple supervisory signal receivers 71a, 71b, . . . , 71n arranged in the above-described way, the present embodiment detects connection state of the printed circuit boards 60 and 70.

It is desired that the wiring lines 63a, 63b, . . . , 63n and the wiring lines 73a, 73b, . . . , 73n be distributed uniformly over the entire length of the connectors 62 and 72. More specifically, those wiring lines cross the connectors 62 and 72 at their one end portion (e.g., the uppermost portion of the connectors 62 and 72 in FIG. 13) and at their other end portion (e.g., the lowermost portion of the connectors 62 and 72 in FIG. 13), as well as at intermediate portions of the connectors 62 and 72. This arrangement of wiring lines enables detection of incomplete connection between the printed circuit boards 60 and 70 even in the case where the coupling of connectors 62 and 72 in FIG. 13 is partly incomplete (e.g., it is loose only at some lower portions of the connectors).

For the above-described supervisory signal sources 61a, 61b, . . . , 61n and supervisory signal receivers 71a, 71b, . . . , 71n, differential signaling techniques may be used to deliver supervisory signals as in the second embodiment described earlier.

Next, a fourth embodiment of the present invention will be described in detail with reference to the accompanying drawings. In the fourth embodiment, the wiring lines for connecting a supervisory signal source and a supervisory signal receiver are arranged in a bellows shape, or in a zigzag pattern.

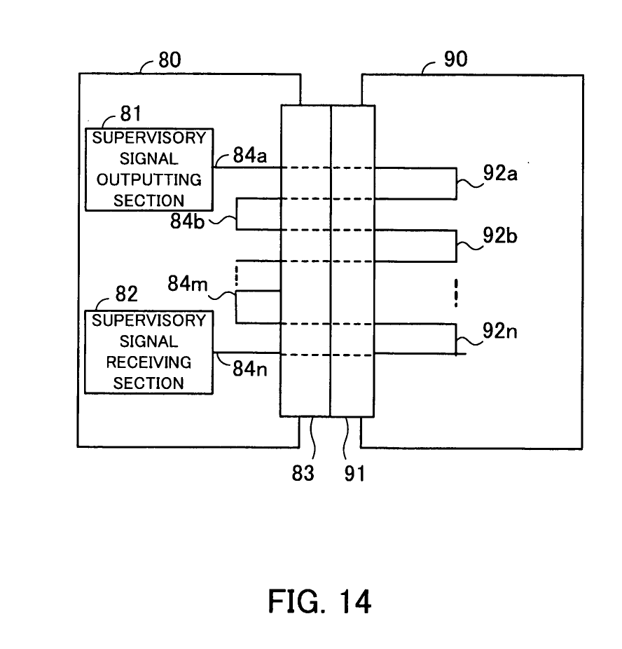

FIG. 14 is a block diagram of a connection failure detection circuit according to the fourth embodiment. Specifically, FIG. 14 shows two printed circuit boards 80 and 90. One printed circuit board 80 has a supervisory signal source 81, a supervisory signal receiver 82, a connector 83, and wiring lines 84a, 84b, . . . , 84m and 84n. Another printed circuit board 90 has a connector 91 and wiring lines 92a, 92b, . . . , 92n. Those printed circuit boards 80 and 90 of FIG. 14 are part of, for example, a data transmission device, one corresponding to its backplane and the other corresponding to a modular unit connected to that backplane. Alternatively, the printed circuit boards 80 and 90 may be modular units connected to each other.

The supervisory signal source 81 on the printed circuit board 80 has the same function as that of the supervisory signal source 11 illustrated in FIG. 2 and therefore, its description will not be repeated here. Further, the supervisory signal receiver 82 on the printed circuit board 80 has the same function as that of the supervisory signal receiver 12 illustrated in FIG. 2 and, therefore, its description will not be repeated here.

On the printed circuit board 80, a wiring line 84a is routed between the output of the supervisory signal source 81 and a terminal of the connector 83. Subsequent wiring lines 84b, . . . , 84m are each routed between two terminals of the connector 83. The last wiring line 84n is routed between the input of the supervisory signal receiver 82 and yet another terminal of the connector 83.

On the opposite printed circuit board 90, a wiring line 92a is routed between two terminals of the connector 91. Similarly, the subsequent wiring lines 92b, . . . , 92n are each routed between two terminals of the connector 91.

The connector 83 and its mating connector 91 are adapted to fit into each other. When those connector 83 and 91 are completely engaged, the uppermost wiring line 84a is connected to one end of the wiring line 92a. The other end of the wiring line 92a is connected to one end of the wiring line 84b. The other end of the wiring line 84b is connected to one end of the wiring line 92b. Subsequent to similar connection between wiring lines, the wiring line 84m is connected to one end of the wiring line 92n. The other end of the wiring line 92n is then connected to one end of the wiring line 84n.

That is, when the connectors 83 and 91 are engaged, the wiring lines 84a, 84b, . . . , 84m, 84n and 92a, 92b, . . . , 92n form a bellows-shaped path that crosses back and forth the connectors 83 and 91. This path interconnects the output of the supervisory signal source 81 and the input of the supervisory signal receiver 82. The supervisory signal receiver 82 receives a supervisory signal from the supervisory signal source 81 through the wiring lines 84a, 84b, . . . , 84n and 92a, 92b, . . . , 92n, thus detecting connection state of the printed circuit boards 80 and 90.

With the wiring lines 84a, 84b, . . . , 84m, 84n and the wiring lines 92a, 92b, . . . , 92n being arranged to form a bellows-shaped path between the supervisory signal source 81 and supervisory signal receiver 82, the present embodiment detects connection state of the printed circuit boards 80 and 90.

It is desired that the wiring lines 84a, 84b, . . . , 84m, 84n and the wiring lines 92a, 92b, . . . , 92n be distributed uniformly over the entire length of the connectors 83 and 91. More specifically, those wiring lines cross the connectors 83 and 91 at their one end portion (e.g., the uppermost portion of the connectors 83 and 91 in FIG. 14) and at their other end portion (e.g., the lowermost portion of the connectors 83 and 91 in FIG. 14), as well as at intermediate portions of the connectors 83 and 91. This arrangement of wiring lines enables detection of incomplete connection between the printed circuit boards 80 and 90 even in the case where the coupling of connectors 83 and 91 in FIG. 14 is partly incomplete (e.g., it is loose only at some lower portions of the connectors).

In FIG. 14, the supervisory signal receiver 82 is mounted on the printed circuit board 80. The present invention, however, should not be limited to this specific configuration. Alternatively, the supervisory signal receiver 82 may be mounted on the opposite printed circuit board 90.

In addition, for the above-described supervisory signal source 81 and supervisory signal receiver 82, differential signaling techniquous can be used to deliver supervisory signals as in the second embodiment described earlier.

Next, a fifth embodiment of the present invention will be described in detail with reference to the accompanying drawings. In the fifth embodiment, one supervisory signal source and a plurality of supervisory signal receivers are provided. Further, the output of the supervisory signal source is branched into a plurality of wiring lines such that a supervisory signal produced by the single supervisory signal source will be distributed to multiple supervisory signal receivers.

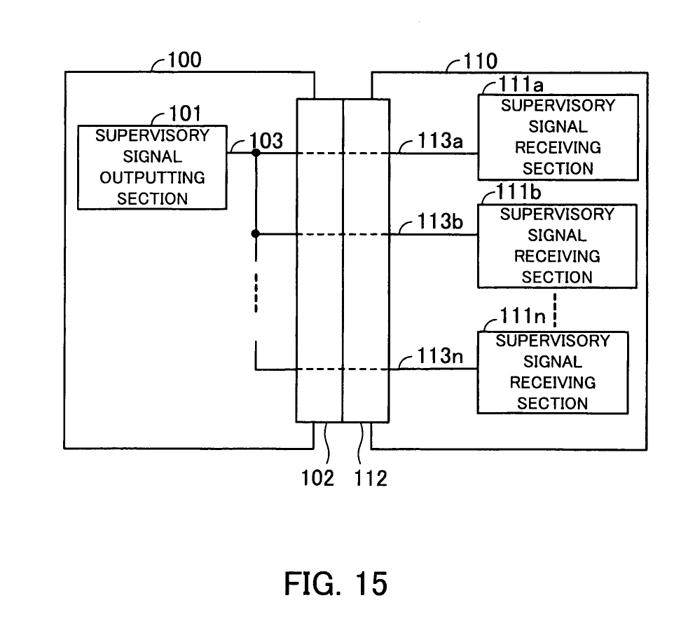

FIG. 15 is a block diagram of a connection failure detection circuit according to the fifth embodiment. Specifically, FIG. 15 shows two printed circuit boards 100 and 110. One printed circuit board 100 has a supervisory signal source 101, a connector 102, and a wiring line 103. Another printed circuit board 110 has supervisory signal receivers 111a, 111b, . . . , 111n, a connector 112, and wiring lines 113a, 113b, . . . , 113n. Those printed circuit boards 100 and the printed circuit board 110 of FIG. 15 are part of, for example, a data transmission device, one corresponding to its backplane and the other corresponding to a modular unit connected to that backplane. Alternatively, the printed circuit boards 100 and 110 may be modular units connected to each other.

The supervisory signal source 101 on the printed circuit board 100 has the same function as that of the supervisory signal source 11 illustrated in FIG. 2 and, therefore, its description will not be repeated here. Further, each supervisory signal receiver 111a, 111b, . . . , 111n on the printed circuit board 110 has the same function as that of the supervisory signal receiver 12 illustrated in FIG. 2 and, therefore, its description will not be repeated here.

On the printed circuit board 100, a wiring line 103 is routed from the output of the supervisory signal source 101 and branched into a plurality of wiring lines each directed to different terminals of the connector 102.

On the opposite printed circuit board 100, a wiring line 113a is routed between the input of the supervisory signal receiver 111a and a terminal of the connector 112. Another wiring line 113b is routed between the input of the unit 111b and another terminal of the connector 112. In the same manner, yet another wiring line 113n is routed between the input of the unit 111n and yet another terminal of the connector 112.

The connector 102 and its mating connector 112 are adapted to fit into each other. When those connectors 102 and 112 are completely engaged, the branches of the wiring line 103 are connected to corresponding wiring lines 113a, 113b, . . . , 113n.

That is, when the connectors 102 and 112 are engaged, the output of the supervisory signal source 101 is connected to the inputs of multiple supervisory signal receivers 222a, 111b, . . . , 111n. The supervisory signal receivers 111a, 111b, . . . , 111n receives a supervisory signal from the unit 101 through the wiring line 103 and the wiring lines 113a, 113b, . . . , 113n, thus detecting connection state of the printed circuit boards 100 and 110.

With the branched wiring line 103 from the supervisory signal source 101, and with multiple supervisory signal receivers 111a, 111b, . . . , 111n, the present embodiment detects connection state of the printed circuit boards 100 and 110.

It is desired that the wiring line 103 with branched ends and the wiring lines 113a, 113b, . . . , 113n be distributed uniformly over the entire length of the connectors 102 and 112. More specifically, those wiring lines cross the connectors 102 and 112 at their one end portion (e.g., the uppermost portion of the connectors 102 and 112 in FIG. 15) and at their other end portion (e.g., the lowermost portion of the connectors 102 and 112 in FIG. 15), as well as at intermediate portions of the connectors 102 and 112. This arrangement of wiring lines enables detection of incomplete connection between the printed circuit boards 100 and 110 even in the case where the coupling of connectors 102 and 112 in FIG. 15 is partly incomplete (e.g., it is loose only at some lower portions of the connectors).

For the above-described supervisory signal source 101 and supervisory signal receivers 111a, 111b, . . . , 111n, differential signaling can be used to deliver supervisory signals as in the second embodiment described earlier.

To summarize the various embodiments described above, the proposed connection failure detection circuit according to the present invention offers a supervisory signal source to produce a supervisory signal and a supervisory signal receiver to receive the supervisory signal. Wiring lines are arranged to form a signal path that crosses connectors of printed circuit boards at at least one point. The supervisory signal receiver determines whether the received supervisory signal carries an expected series of logical values.

When the connection between the printed circuit boards is in an incomplete state, the resulting impedance mismatch hampers the supervisory signal receiver from identifying expected logical values. The supervisory signal receiver can therefore detect the incomplete connection between the two printed circuit boards.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A connection failure detection circuit for detecting connection failure between first and second printed circuit boards connected via connectors, the circuit comprising:
a supervisory signal source mounted on the first printed circuit board to produce a supervisory signal;
a supervisory signal receiver mounted on the first or second printed circuit board to receive the supervisory signal produced by the supervisory and determine whether the received supervisory signal carries expected logical values; and
wiring lines for delivering the supervisory signal from the supervisory signal source to the supervisory signal receiver, the wiring lines being arranged to form a signal path that crosses the connectors at at least one point.

2. The connection failure detection circuit according to claim 1, wherein:
the supervisory signal is a clock signal; and
the supervisory signal receiver determines whether the received supervisory signal carries a series of alternate logical values.

3. The connection failure detection circuit according to claim 1, wherein:
the supervisory signal is a pseudo-random noise (PN) pattern signal; and
the supervisory signal receiver determines whether the received supervisory signal carries a series of logical values that matches with an original PN pattern of the PN pattern signal.

4. The connection failure detection circuit according to claim 1, wherein:
the supervisory signal receiver samples the supervisory signal at a frequency higher than that of the supervisory signal.

5. The connection failure detection circuit according to claim 1, wherein:
an impedance mismatch exists between the supervisory signal source and supervisory signal receiver and the wiring lines.

6. The connection failure detection circuit according to claim 1, wherein:
the supervisory signal has a higher frequency than other signals exchanged between the first printed circuit board and the second printed circuit board.

7. The connection failure detection circuit according to claim 1, wherein:
the supervisory signal source and supervisory signal receiver use differential signaling to transmit and receive the supervisory signal.

8. The connection failure detection circuit according to claim 7, wherein:
the wiring lines for delivering complementary signals of the differential supervisory signal have different lengths.

9. The connection failure detection circuit according to claim 7, wherein:
the differential signaling used is Low Voltage Differential Signaling (LVDS), and
the connection failure detection circuit further comprises a terminating resistor having a resistance value other than 100Ω.

10. The connection failure detection circuit according to claim 1, comprising: a plurality of the supervisory signal sources;
a plurality of the supervisory signal receivers; and
a plurality of the wiring lines routed between the supervisory signal sources and the supervisory signal receivers.

11. The connection failure detection circuit according to claim 1, comprising a plurality of the supervisory signal receivers;
wherein the wiring lines comprises a plurality of branched wiring lines routed from the supervisory signal source so as to deliver the supervisory signal to the plurality of the supervisory signal receivers.
